(19) United States
(12) Patent Application Publication
(10) Pub. No.: US 2023/0298158 A1
(43) Pub. Date: Sep. 21, 2023

(54) APPARATUS AND METHOD FOR SELECTING HIGH QUALITY IMAGES FROM RAW IMAGES AUTOMATICALLY

(71) Applicant: ASML NETHERLANDS B.V., Veldhoven (NL)

(72) Inventors: Jiao HUANG, Shenzhen (CN); Jinze WANG, Shenzhen (CN); Hongfei SHI, Shenzhen (CN); Mu FENG, San Jose, CA (US); Qian ZHAO, San Jose, CA (US); Alvin Jianjiang WANG, Fremont, CA (US); Yan-Jun XIAO, Shenzhen (CN); Liang LIU, Shenzhen (CN)

(73) Assignee: ASML NETHERLANDS B.V., Veldhoven (NL)

(21) Appl. No.: 18/017,646

(22) PCT Filed: Jul. 20, 2021
(86) PCT No.: PCT/EP2021/070206

§ 371 Date: Jan. 23, 2023

(30) Foreign Application Priority Data
Aug. 19, 2020 (WO) PCT/CN2020/109993

(51) Int. Cl. G06T 7/00; G06T 7/13

(52) U.S. Cl. CPC G06T 7/001; G06T 7/13; G06T 2207/30168; G06T 2207/30148; G06T 2207/20216; G06T 2207/10061

(57) ABSTRACT

A method for selecting good quality images from raw images of a patterned substrate. The method includes obtaining a plurality of raw images (e.g., SEM images) of a patterned substrate; determining a raw image quality metric (e.g., an image score, an average slope, distance between contours) based on data associated with one or more gauges or one or more contours of one or more features within each image of the plurality of raw images, the raw image quality metric being indicative of a raw image quality; and selecting, based on the raw image quality metric, a sub-set of raw images from the plurality of raw images. The sub-set of raw images can be provided for performing more accurate measurements of the one or more features within an image.

### CROSS-REFERENCE TO RELATED APPLICATIONS

This application claims priority of PCT application PCT/CN2020/109993 which was filed on Aug. 19, 2020 and which is incorporated herein in its entirety by reference.

### TECHNICAL FIELD

The description herein relates generally to metrology or inspection in semiconductor manufacturing. More particularly, apparatuses, methods, and computer program products for using automatic selection of images for performing high-quality metrology or inspection related to lithographic process.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involve processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

### SUMMARY

In an embodiment, there is provided a method for improving quality and accuracy of metrology or inspection related to a patterned substrate. The method includes obtaining a plurality of raw images of a patterned substrate; determining a raw image quality metric based on data associated with gauges or contours of one or more features within each image of the plurality of raw images, the raw image quality metric being indicative of a raw image quality; selecting, based on the raw image quality metric, a sub-set of raw images from the plurality of raw images; and providing the sub-set of raw images for performing measurements associated with the one or more features within an image.

In an embodiment, the selection can be based on an image score assigned to a raw image based on specified criteria related to gauges of the raw image. The selection process involves analyzing, based on the specified criteria, gauge data associated with the gauges each image of the plurality of raw images. For example, the specified criteria include but not limited to existing of particular gauges, missing gauges, whether gauge data associated with a particular gauge falls within a cluster, whether gauge data is an outlier in corresponding gauge group, whether gauge group data is over specified criteria, etc.

The present approach enables automatic selection of good images and removal bad quality raw images without the need of manually review the raw images. This automatic selection process can effectively save modeling time (e.g., OPC modeling) as well. The criteria of the image scoring have physical meanings. As such, the present disclosure can comprehensively consider different issues associated with the patterning or metrology process, and filter out bad raw images. Additionally, an issue report for the bad raw images may be generated to guide a user to e.g., improve an imaging process, defect inspection, or metrology recipe.

In an embodiment, the raw image quality metric is a function of a contrast at the gauges associated with each raw image. For example, the metric is an average of slopes determined at the gauges associated with each raw image.

The use e.g., slope as the raw image quality metric makes the selection process robust to noise because a quality of image is determined for a gauge region, thus less affected by image noise elsewhere in the image. Hence, even if there is significant noise outside the gauge regions, an image may be selected as a good quality image. In the present case, a detailed statistical analysis of a set of raw images may not be performed, as such the present approach can be applied to a low number raw images (e.g., 5-10 image).

In an embodiment, the determining of the raw image quality metric is based on contour analysis of the raw images. In an embodiment, determining a distance between the first contour with the second contour. The first contour is obtained for a feature within an average image of the plurality of raw images associated with a particular pattern or a reference raw image selected from the raw images. The second contour is obtained for the feature from each of the raw image associated with the particular pattern; and

According to an embodiment, there is provided a computer system comprising a non-transitory computer readable medium having instructions recorded thereon. The instructions, when executed by a computer, implement the method steps above.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed embodiments. In the drawings,

FIG. 1 illustrates a block diagram of various subsystems of a lithographic projection apparatus, according to an embodiment.

FIG. 2 illustrates an exemplary flow chart for simulating lithography in a lithographic projection apparatus, according to an embodiment.

FIG. 3 is a flow chart of a method for selecting good quality images (e.g., SEM images) form a set of raw images, according to an embodiment.

FIG. 4A is a flow chart of a process of determining an image quality metric based on which good quality images are selected (in FIG. 3), according to an embodiment.

FIG. 4B are exemplary patterns and gauges used for determining the metric of FIG. 4A, according to an embodiment.

FIG. 4C illustrates sample SEM images and its image scores based on which good quality images are selected, according to an embodiment.

FIG. 5 illustrates exemplary SEM images, each SEM image overlaid with gauges used for determining an image quality metric, according to an embodiment.

FIG. 6A is a flow chart of a process of determining another image quality metric based on which good quality images are selected (in FIG. 3), according to an embodiment.

FIG. 6B illustrates example of contour-to-contour offset measurement (e.g., distance), according to an embodiment.

FIG. 7 is a block diagram of an example metrology system, according to an embodiment.

FIG. 8 is a process flow diagram of an example implementation of an improved metrology process, according to an embodiment.

FIG. 9 is a block diagram of an example computer system, according to an embodiment.

FIG. 10 is a schematic diagram of a lithographic projection apparatus, according to an embodiment.

FIG. 11 is a schematic diagram of another lithographic projection apparatus, according to an embodiment.

FIG. 12 is a detailed view of the lithographic projection apparatus, according to an embodiment.

FIG. 13 is a detailed view of the source collector module of the lithographic projection apparatus, according to an embodiment.

FIG. 14 schematically depicts an embodiment of an electron beam inspection apparatus, according to an embodiment.

FIG. 15 schematically illustrates a further embodiment of an inspection apparatus, according to an embodiment.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” may be used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.

An example of a programmable LCD array is given in U.S. Pat. No. 5,229,872, which is incorporated herein by reference.

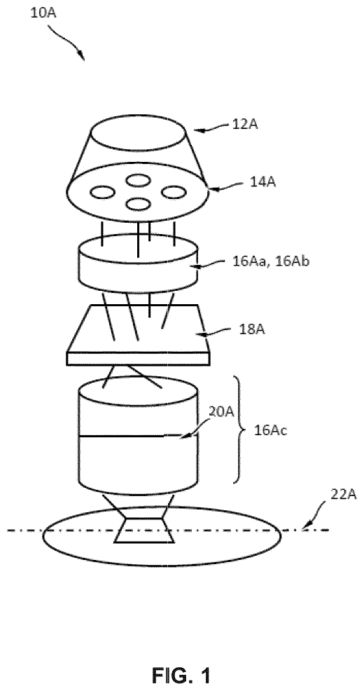

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

According to an embodiment of the present disclosure, one or more images may be generated. The images includes various types of signal that may be characterized by pixel values or intensity values of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image. In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be signal having intensity less than 50% of the highest intensity of the pixel (e.g., pixels corresponding to target pattern may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

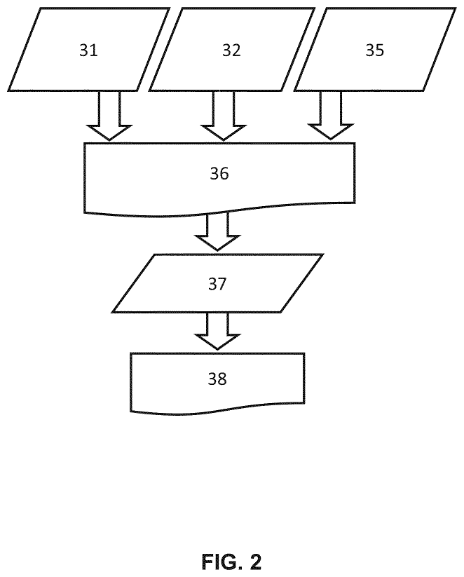

FIG. 2 illustrates an exemplary method for simulating lithography in a lithographic projection apparatus, according to an embodiment. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (σ) settings as well as any particular illumination shape (e.g. off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

CF(z₁,z₂, . . . ,z_{N})=Σₚ₌₁^{P}wₚfₚ²(z₁,z₂, . . . ,z_{N}) (Eq. 1)

where (z₁, z₂, . . . , z_{N}) are N design variables or values thereof. fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in Eq. 1. CF(z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ(z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “patterning process” generally means a process that creates an etched substrate by the application of specified patterns of light as part of a lithography process. However, “patterning process” can also include plasma etching, as many of the features described herein can provide benefits to forming printed patterns using plasma processing.

As used herein, the term “target pattern” means an idealized pattern that is to be etched on a substrate.

As used herein, the term “printed pattern” or “patterned substrate” means the physical pattern on a substrate that was imaged and/or etched based on a target pattern. The printed pattern can include, for example, troughs, channels, depressions, edges, or other two and three dimensional features resulting from a lithography process.

As used herein, the term “process model” means a model that includes one or more models that simulate a patterning process. For example, a process model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), and an OPC model (e.g., that can be used to make target patterns and may include sub-resolution resist features (SRAFs), etc.).

An existing tool (e.g., metrology of eXtreme Performane (MXP)) is configured to output gauges such as CD or EP gauges or contour that can be used for, e.g., optical proximity correction (OPC) modeling. The existing tool averages a set of raw images (e.g., scanning electronic microscope (SEM) images of a patterned substrate) and extracts a contour associated with a feature from averaged image. Such contours are more reliable than extracting contour from raw image. Also the tool directly determines CD/EP for the extracted contour.

Currently there are two main technologies for raw image cleaning. First, manually review a raw image one by one, and remove bad quality raw images. Second, use a machine learning model to identify bad quality raw images.

However, there are also some limitations associated with existing technology. Identifying and removing bad quality raw images through manually review requires substantial manual effort. As such, the metrology turn-around-time from measuring a patterned substrate to providing CD/EP data will be very long. For example, there may be 20,000 raw images of a pattered substrate. If it takes approximately 3 seconds to review one raw image, then a total review time will be approximately 17 hours, nearly 2 to 3 work days to do remove bad quality images. If there are more patterns per image, then the image review time will be even longer. In addition, the manual review process is typically performed by experienced engineer, and identifying bad images will be subjective that will influence the metrology accuracy. As such, there is a need for improved methods for selecting good quality raw images that are not subjective or require manual review.

Using a machine learning (ML) model to identify bad quality raw images may depend on way measurements are performed. For example, SEM image can be very different due to different scanning machine, and its scan setting. As such, it may be difficult to adapt current ML based method to different kinds of SEM images. As such, improved methods for selecting good quality raw images is desired.

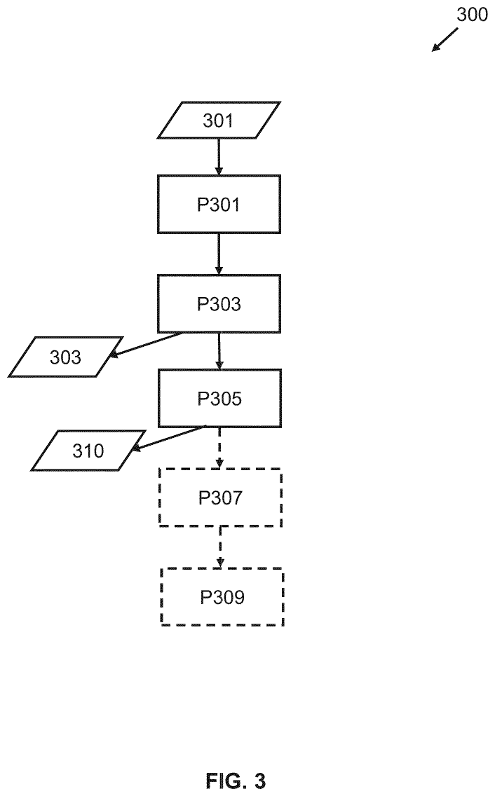

FIG. 3 is a flow chart of a method 300 for selecting captured images of a patterned substrate. The method 300 includes following processes P301, P303, and P305 for selecting good quality images. Further, the method 300 can be further extended to employ the selected good quality raw images in processes P307 for performing accurate measurements of features. In an embodiment, the measurements based on the selected raw images can be further used to improve process models related to lithographic process. For example, the selected raw images can be used for improving optimal proximity correction models to determine mask patterns.

Process P301 includes obtaining a plurality of raw images 301 of a patterned substrate. In an embodiment, the plurality of raw images 301 are images acquired via an image capture device such as a scanning electron microscope (SEM). These raw SEM images may include some bad quality images resulting poor focus, imaging errors that results in a poorly patterned substrate, errors in capturing images of a patterned substrate, or other issues resulting in bad quality images being captured by an image capture device (e.g., SEM). In an embodiment, the raw image can be images on which no image processing or minimum image processing operations are performed. In an embodiment, after an image is captured by an image capturing device (e.g., SEM), minimal image processing may be performed on the captured image to generate a raw image. For example, the image processing can be denoising the image, removing blur from the image, alignment with respect to a reference, cropping a portion of the image, etc. In an embodiment, such image processing may be performed by an image capture device (e.g., SEM). A raw image is not a combination of images such as average image generated by averaging a plurality of raw images.

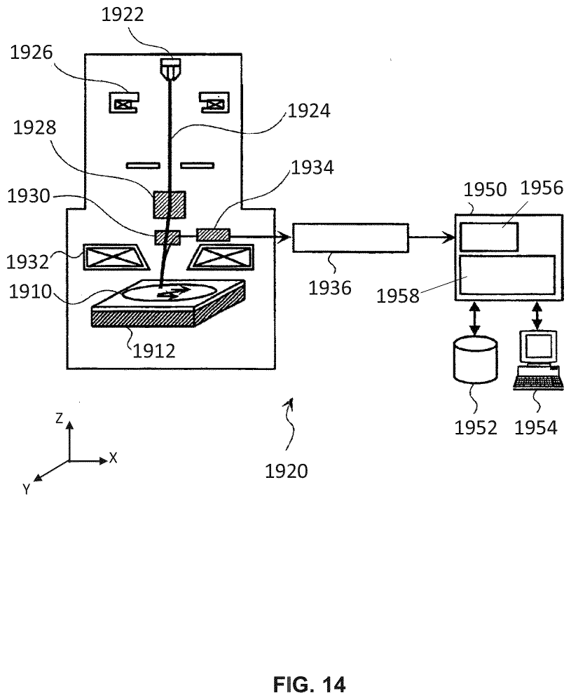

Process P303 includes determining a raw image quality metric 303 based on data associated with gauges or contours of one or more features within each image of the plurality of raw images 301, the raw image quality metric 303 being indicative of a raw image quality. In an embodiment, the gauges may be generated by a metrology tool or an inspection tool (e.g., FIGS. 14 and/or 15) configured to generate gauges for any input image. The gauges can be markers overlaid on a feature in the image in order to measure, e.g., geometric properties of the feature. In an embodiment, gauges correspond to imaginary lines that intersect the contour of the shape(s) that is measured and, more specifically, the gauges are the points where the imaginary lines respectively intersect the shape(s) such the applicable geometric dimensions can be determined. In an embodiment, contours refer to an outlines of a feature in the image. In an embodiment, the metrology tool or the inspection apparatus (e.g., FIGS. 14 and/or 15) are configured to extract a contour of the feature in any input image. For example, the contour can be extracted using a contour extraction algorithm based on image intensities associated with e.g., an edge of a feature. The present disclosure is not limited to a particular gauge generation or contour extraction approaches.

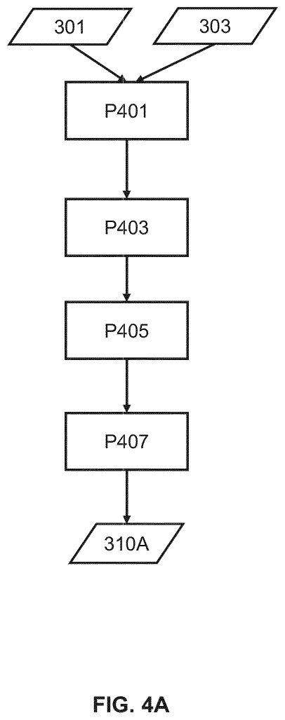

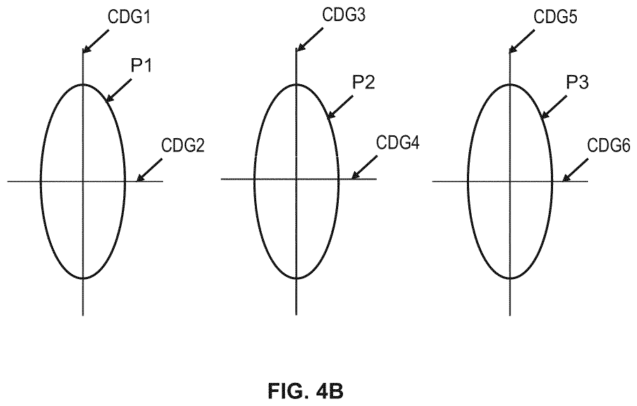

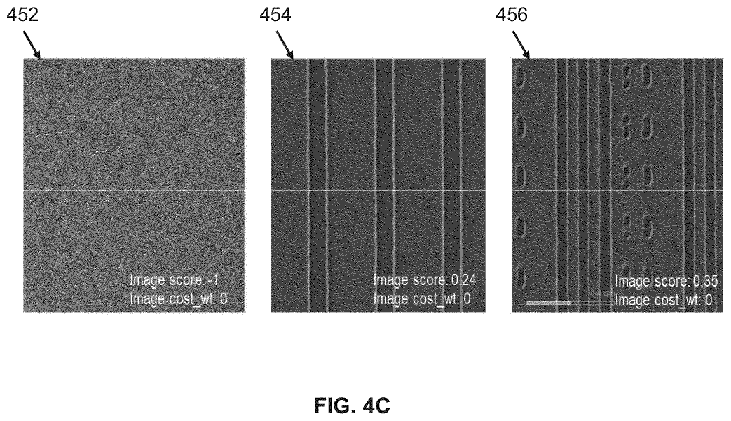

According to some embodiments, the process P303 can be implemented in different ways. Exemplary implementations of the process P303 are further discussed in detail with respect to FIGS. 4A, 5, and 6A below.

Referring back to FIG. 3, process P305 includes selecting, based on the raw image quality metric 303, a sub-set of raw images 310 from the plurality of raw images 301. For example, selecting raw images whose raw image quality metric 303 value is above a selection threshold. In an embodiment, the selection threshold may depend on the type of metric used. Example of the metric include but limited to an image score (e.g., determined using processes in FIG. 4A), an average slope associated with the gauges, a difference between contours, as discussed herein. In an embodiment, the selection threshold may be defined by a user, for example based on an inspection or analysis of a good quality image.

In an embodiment, the method 300 can further include outputting the selected sub-set of raw images 310 for improving various aspect related to the patterning process. In an embodiment, the method 300 includes process P307 that provides the sub-set of raw images 310 for performing measurements associated with the one or more features within an image. In an embodiment, the method 300 includes process P309, wherein the selected sub-set of images can be used for training a model associated with a patterning process. For example, training a machine learning model, or other models associated with optical proximity correction (OPC). The aforementioned examples are provided by way of example. The present disclosure is not limited to a particular application of the sub-set of images selected according to method 300 herein.

In an embodiment, the process 303 of determining the raw image quality metric 303 (also referred as an image score in the present embodiment) is described with respect to processes in FIG. 4A. For example, the determining of the raw image quality metric 303 includes analyzing, based on specified criteria, gauge data associated with the gauges each image of the plurality of raw images 301. Examples of specified criteria include but not limited to existing of particular gauges, missing gauges, whether gauge data associated with a particular gauge falls within a cluster, whether gauge data is an outlier in corresponding gauge group, whether gauge group data is over specified criteria, etc. Examples of gauges and application of exemplary criteria based on the gauges for assigning values to the metric 303 are further discussed in detail below.

An example of gauges is illustrated in FIG. 4B. The present example shows patterns depicted for two-dimensional metrology. FIG. 4B illustrates an ellipse gauge pattern. Gauges correspond to imaginary lines that intersect the contour of the shape(s) that is measured and, more specifically, the gauges are the points where the imaginary lines respectively intersect the shape(s) such the applicable geometric dimensions can be determined. For example, in FIG. 4B, example gauges correspond to the imaginary lines CDG1, CDG2, CDG3, CDG4, CDG5, and CDG6 that are superimposed on the contour of the shape depicted therein. These gauges CDG1-CDG6 are referred as CD gauges used to measure CD of a feature. For example, the gauge CDG1 is used for measuring CD in the Y-direction and the gauge CDG2 is used for measuring CD in the X direction. The gauges are determined at the points where the imaginary lines respectively intersect the shape such that the applicable geometric dimensions can be determined.

Although only two gauges are shown in FIG. 4B, the number of gauges may be fewer or more than shown, typically much more than shown. Similarly, the gauges may be in different directions, between different shape parts, etc. For each pattern or more likely a plurality of patterns, there may be tens, hundreds, thousands if not millions, of actual or possible gauges.

Referring to FIG. 4A, the analyzing of the gauges for assigning values to the metric 303 includes following processes. Process P401 includes determining whether the gauge data associated with the gauges exists for a given raw image of the plurality of raw images 301; responsive to the gauge data not existing, assigning a first value to the raw image quality metric 303, the first value being lower than a selection threshold; or responsive to the gauge data exists, assigning a second value to the raw image quality metric 303, the second value being higher than the selection threshold. For example, the first value can be −1, the second value can be 1, and the selection threshold can be 0.3. In an embodiment, other values may be assigned to the metric 303.

In an embodiment, a metrology tool or a processor (e.g., FIGS. 14 and/or 15) may be configured to generate gauges for an input image (e.g., a SEM image) of a patterned substrate. The gauges may be provided in an electronically exchangeable file format. In an embodiment, the gauge file comprises gauge data such as CD gauges, EP gauges, or other measurement markers associated with one or more features within the input image (e.g., a SEM image).

If there is no CD/EP gauge file generated for a raw SEM image or the generated gauge file is empty, then it is treated as a blank or out of focus image; in this case, assign an image score (an example of a raw image quality metric 303) a value of −1; otherwise, assign the image score a value of 1. Optionally, the process P401 may be configured to generate an issue report. For example, an issue reports comprises an indication of a blank or an out-of-focus image issue.

In an embodiment, process P403 includes determining whether the gauge data is missing a particular gauges (e.g., CD gauges) for the given raw image of the plurality of raw images 301; and responsive to the missing the particular gauges (e.g., CD gauges), reducing the second value of the raw image quality metric 303 by a specified amount. In an embodiment, the specified amount is computed as an inverse of a product of a number of gauge types and a number of repeating patterns. Optionally, the process P403 may be configured to generate an issue report. For example, an issue reports comprises an indication of a missing gauge.

For example, in a CD gauge file for each raw image, total gauge number equals a product of gauge types a number of repeating patterns. For example, referring to FIG. 4B, a raw gauge file may include 2 different gauge types (e.g., CD gauges in Y-direction such as CDG1 and CD gauges in X-direction such as CDG2), and 3 repeating patterns. Hence, the gauge file may include 6 gauges. For each missing gauge, the image score is reduced by 1/(gauge type*number of repeating patters). For example, the image score 1 may be reduced by 1/6, 2/6, or 3/6.

In an embodiment, the determining the raw image quality metric 303 may further include process P405. The process P405 includes clustering the gauge data associated with the gauges of the plurality of raw images 301. In an embodiment, the gauge data is gauge data associated with a particular gauge type (e.g., EP gauge data, or CD gauge data); and modifying, based on the clustering, the second value of the raw image quality metric 303.

In an embodiment, the process P407 includes determining whether the gauge data (e.g., EP gauge data or CD gauge data) of one or more raw images of the plurality of raw images 301 are outside a specified cluster region; and responsive to the gauge data (e.g., EP gauge data or CD gauge data) being outside the specified cluster region, reducing the second value of the raw image quality metric 303 associated with the one or more raw images to be lower than the selection threshold.

In an embodiment, the modifying the second value of the raw image quality metric 303 includes determining whether the gauge data (e.g., EP gauge data or CD gauge data) of one or more raw images of the plurality of raw images 301 are within a specified cluster region; and responsive to the gauge data (e.g., EP gauge data or CD gauge data) being within the specified cluster region, modifying the second value of the raw image quality metric 303 associated with the one or more raw images based on a statistic associated with a particular gauge data (e.g., CD gauge data).

In an embodiment, clustering may be based on die-to-die (D2D) offset between two gauges. For example, a distance between EP gauges or centers of contours of raw images of a particular pattern may be determined. If the distances are close to each other, and can be clustered into one (e.g., all gauge data points are within a specified cluster region). This also indicates there is no D2D large offset between gauges of two different raw images. However, if the clustered data is outside a specified cluster regions, it indicates there is big difference between raw images. In this case, select raw images in the biggest cluster and assign other raw images an image score value of 0. Optionally, the process P407 may be configured to generate an issue report. For example, an issue reports comprises an indication of a large die-to-die offset.

In an embodiment, the modifying the second value of the raw image quality metric 303 includes determining whether the statistic associated with the particular gauge data (e.g., CD gauge data) are outside a statistic threshold; and responsive the gauge data (e.g., CD gauge data) being outside the statistic threshold, reducing the second value of the raw image quality metric 303 of the one or more raw images by a specified amount. In an embodiment, the specified amount is computed as an inverse of a product of number of gauge types and number of repeating patterns.

In another example, clustering can be based on statistical analysis of gauge data. For example, the statistical analysis comprises determining a statistic such as a standard deviation, mean, median, quantile, absolute error range, relative error range, min, max of CD gauge. Based on the statistical analysis, for patterns with raw images have the statistic in one cluster, then raw images within the specified cluster region is selected. For each gauge being an outlier, the image score with associated raw image is reduced by 1/(gauge types*a number of repeating patterns).

The gauge types discussed herein are presented by example without limiting the scope of the present disclosure. In an embodiment, contour or co-ordinate type parameters may be used to instead of or in conjunction with CD/EP gauge. In an embodiment, other type of data associated with the raw image or gauge attribute, like intensity, contrast, ILS etc. may be analyzed to determine the quality of a raw image.

As discussed herein, the method 300 can further include a process (e.g., P401, P403) for generating an issue report for each raw image whose raw image quality metric 303 that does not satisfy the selection threshold. For example, an example issue report for the bad raw images, includes but not limited to, issues such local blur, an out-of-focus raw image, a blank raw image, a large white band within a raw image, large process variance within a raw image, a large D2D offset between different raw images, or other issues causing bad raw images.

Accordingly, the specified criteria in the exemplary process of FIG. 4A, discussed above, can results in selection of a sub-set of raw images 310A from the raw images 301. An example application of process FIG. 4A is illustrated in FIG. 4C.

FIG. 4C illustrates example raw SEM images whose raw image quality metric 303 that does not satisfy a selection threshold (e.g., 0.5), as such indicative of bad quality images. For example, a raw image 452 having blank or no feature gets assigned an image score of −1, a raw image 454 having large white bands around the features gets assigned an image score of 0.24, and a raw image 456 having a relatively high amount of local blur gets assigned an image score of 0.35.

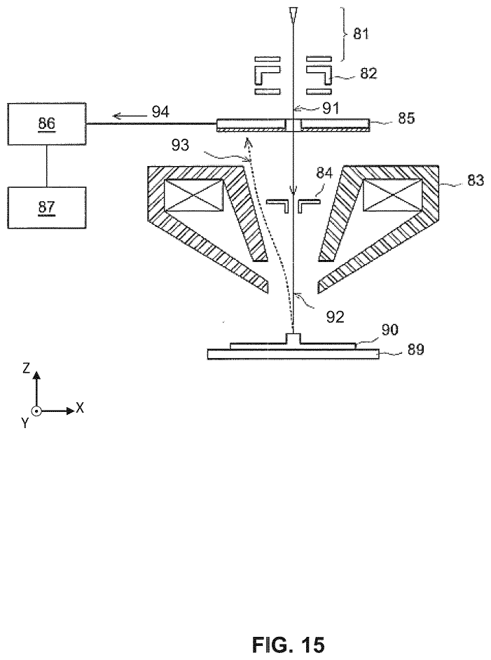

The present embodiment, referring to FIGS. 4A-4C, has several advantages. An existing tool (e.g., SEM metrology tool (FIG. 14) or inspection apparatus (FIG. 15)) may be modified to automatically identify good images and remove bad quality raw images without the need of manually review the raw images. Alternatively a separate software program may be implemented. This automatic selection process can effectively save modeling time as well. For example, OPC modeling to determine a mask pattern is a time consuming process. Using good quality SEM images in OPC process, can improve simulation time and produce results in relatively less time. As discussed, the selection of good quality raw images is based on mathematical analysis for gauges generated by the metrology tool or a processor. Rules of the image scoring have physical meanings. The example image scoring process of FIG. 4A, has high adaptability for different use cases. Hence, even if the SEM image scanning recipes are very different from for different users, the selection process can be adapted to it. As such, the present disclosure can comprehensively consider different issues related to patterning process or metrology process, and filter out bad raw images which may not be filtered out through e.g., a contour based analysis. Additionally, an issue report for the bad raw images may be generated to guide a user to e.g., improve an imaging process, defect inspection, or metrology recipe.

In another embodiment, the process 303 of determining the raw image quality metric 303 includes performing statistical analysis on gauge data of the gauges associated with each raw image to generate the raw image quality metric 303. In an embodiment, the raw image quality metric 303 is a function of a contrast at the gauges associated with each raw image. In an embodiment, the raw image quality metric 303 is an average of slopes determined at the gauges associated with each raw image. In an embodiment, a slope of a given gauge measures a steepness of a given image in transition from relatively bright region to dark region at a given gauge.

For example, the raw image quality metric 303 can be computed using the following slope equation:

|Σ_{g,p=1,1}^{G,P}slope_{n,m,g,p}|/(P*G)

In the above equation, N is number of patterns, M is number of raw images of each pattern, G is number of gauges associates with a pattern, and P: number of repeats of each gauge within each pattern.

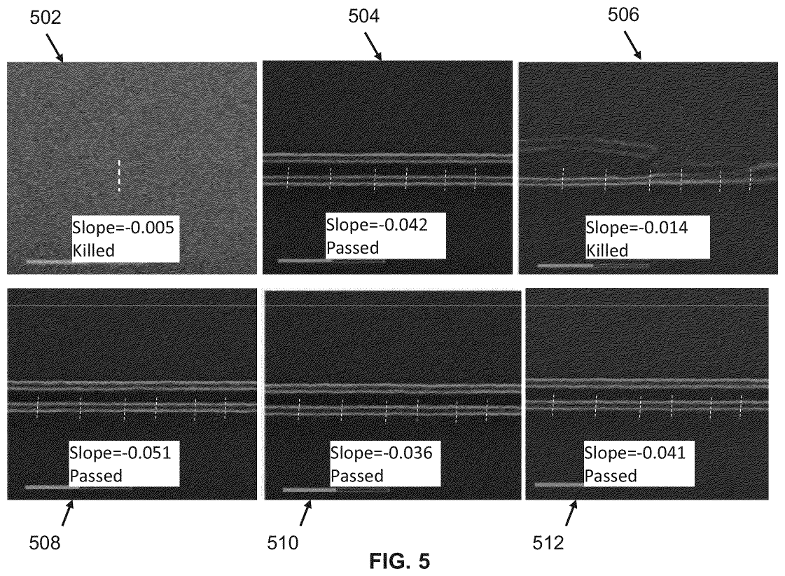

FIG. 5 illustrates example SEM images and corresponding slope values determined based on gauges (see imaginary white lines interposed perpendicular to horizontal line features in the SEM images) of the SEM images. For example, applying the above slope equation to a raw image 502 gives a raw image quality metric value of 0.005. Similarly, a raw image 504 gets a metric value of 0.042, a raw image 506 gets a metric value of 0.014, a raw image 508 gets a metric value of 0.051, a raw image 510 gets a metric value of 0.036, and a raw image 512 gets a metric value of 0.041. In an embodiment, raw images whose quality metric value exceed a selection threshold of e.g., 0.03 may be selected. Accordingly, raw images 504, 508, 510, and 512 may be selected as good quality images.

The present embodiment has several additional benefits. The raw image quality metric is robust to noise because a quality of image is determined for a gauge region, thus less affected by image noise elsewhere in the image. Hence, even if there is significant noise outside the gauge regions, an image may be selected as a good quality image. For example, for images with good quality at gauge region, but bad quality (e.g., due to missing/sbar printing/collapsing features) at other region, the raw image quality metric may still be selected. The present approach may be applied even if there are a low number raw images, as it does not rely on image statistics (e.g., average pixel intensities, variation in pixel intensities across different images, etc.). For example, the approach can be applied for less than 10 raw images per pattern. In the present disclosure, the raw image quality metric can judge the raw image quality based on information within the raw image itself, leading to more stable result.

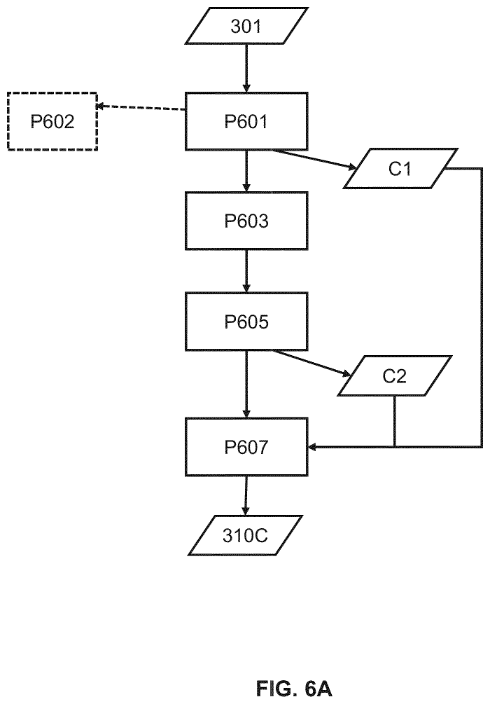

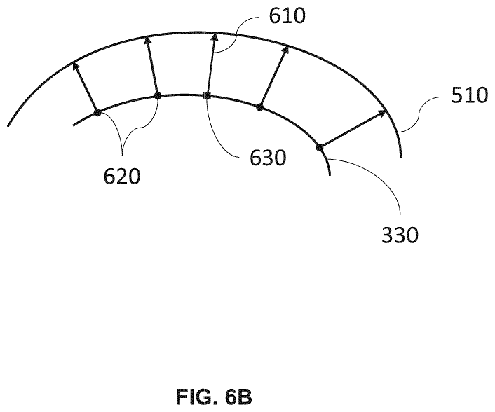

In an embodiment, the process 303 of determining the raw image quality metric 303 is described with respect to processes in FIG. 6A. In an embodiment, the raw image quality metric 303 is determined with respect to an average image or a reference raw image. In an embodiment, all raw images of a same pattern may be aligned with respect to a reference raw image selected from these raw images, and average image may be determined. The average image will also be in same coordinate as the raw images.

In FIG. 6A, process P601 includes obtaining a first contour C1 of a feature within an image. In an embodiment, the first contour C1 is extracted from an average image of the plurality of raw images 301 associated with a particular pattern. In an embodiment, the first contour C1 can also be obtained from a first raw image. As an example, the average image is obtained by clustering of the raw images 301 based on a characteristic of the feature; and averaging a cluster of raw images 301 within a specified cluster region. As another example, the average image is obtained by: aligning the raw images 301 of the particular pattern; clustering the raw images 301 based on mutual distances between contours of a feature within each of the raw images 301; and averaging the cluster of raw images 301 within the specified cluster region to determine the average image. The first contour C1 can be extracted from the average image.

Process P603 includes obtaining a second contour C2 of the feature from each of the raw image associated with the particular pattern. In an embodiment, the obtaining of the second contour C2 comprises process P605. The process P605 includes determining an image property at the contour locations associated with the feature within a given raw image; determining whether the image property breaches a threshold; and responsive to the image property breaching the threshold, extracting the second contour C2 of the feature from the given raw image. In an embodiment, the image property is a local edge sharpness or contrast value at a location associated with the feature, or intensity at a contour of the feature. For example, the slope can be determined at a ridge of the features. A ridge of the feature can be determined by extracting a signal from the image along the gauge. At the peak of the signal, the slope may be determined.

Process P607 includes determining the raw image quality metric e.g., a distance between the first contour C1 with the second contour C2. For example, distance between the first contour C1 extracted from the average image and the second contour C2 of the raw image. The distance metric is presented as an example and not limited to average image.

In an embodiment, the determining of the raw image quality metric 303 includes obtaining raw image contours (e.g., C1 and C2) of a feature within each raw image of the plurality of raw images 301 associated with a particular pattern; and determining matrix of distances between a contour of each raw image of the plurality of raw images 301 with a contour of each another raw image of the plurality of raw images 301. In an embodiment, the sub-set of raw images 310C is selected based on a number of distances associated with each raw image satisfying a selection threshold. For example, for there are 11 raw SEM images, a 10×10 matrix of distances can be determined. For each raw image, there will be 10 distances computed with respect to other raw images. Each distance may be compared with the specified threshold to determine. Then, a raw image cluster that satisfy thresholds may be selected. For example, images with 6 distances satisfying the specified threshold may be selected when all other images cluster has less than or equal to 5 images satisfying the specified threshold.

FIG. 6B illustrates an exemplary method of determining offset between two contours of a feature extracted from two images, according to an embodiment. In an embodiment, a first contour can be extracted from an average image contour or a raw image contour and a second contour can be extracted from a raw image contour. In an embodiment, the contour-to-contour offset can be determined between contours of two raw images.

In an embodiment, determining the distances between contours include aligning contours or images. As used herein, “offset 610” means a distance between a point on a first contour 330, and another point on a second contour 510. In an embodiment, the second contour can be extracted from a raw image. In an embodiment, the first contour 330 can be extracted from an average of the plurality of raw images. In an embodiment, the first contour 330 can be extracted from a raw image. The present disclosure can determine the offset 610 using different methods. For example, the offset 610 can be determined based on coordinates 620 substantially defining a portion of the contour (e.g., 330). As used herein, the term “coordinates” means coordinates that define a portion of or entire contour. In an embodiment, coordinates can be generated by the imaging device, by analysis of images taken by the imaging device, etc. For example, coordinates can be pixel positions that have been determined to correspond to an edge of a contour. Accordingly, an edge detection program can generate the coordinates 620 based on image processing of an image. Examples of coordinates 620 are illustrated in FIG. 6B by circles on the contour 330.

In one embodiment, the offset 610 can be further determined based on distances between the coordinates 620 and the contour 510. In some specific embodiments, the distances can be in directions perpendicular to the contour 330 at the coordinates 620. In other embodiments, the offset 610 may be determined by for example, summing the squares of distance of some or all offsets, or summing some or all offsets, or quantile statistic of these distances. This can be performed, for example, with the x-component and/or the y-component of the perpendicular offset vector.

In some embodiments, any number of additional points (e.g., edge placement (EP) coordinates) may be generated on the contour 330 or 510. As used herein, EP coordinates 630 (also referred to herein as an EP gauge), is an additional point that defines the contour 330 or 510. One example of the EP coordinate 630 is illustrated in FIG. 6B by the solid square located on the contour 330. In some embodiments, the EP coordinates 630 can be generated by interpolating between two or more coordinates 620. In other embodiments, the EP coordinate 630 can be generated by extrapolating from two or more coordinates 620. Accordingly, the offset 610 can be further determined based on the EP coordinate 630, alternatively or in addition to, the coordinates 620.

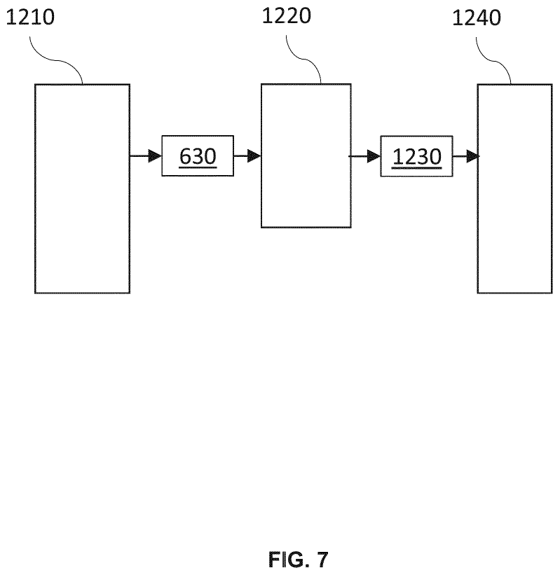

FIG. 7 is a block diagram of an example metrology system, according to an embodiment. The embodiments described herein can be implemented on any number and combination of computing systems, image capture devices, servers, and user interfaces. One exemplary system is illustrated in FIG. 7, where cluster 1210, which may optionally contain any number of computers operating in series and/or parallel, can be configured to allow selection and transmission of EP coordinates 630, also referred to herein as EP gauges 630. EP gauges 630 can be transmitted to one or more managing servers 1220, where recipe 1230 can be sent to image capture device 1240. Recipe 1230 can include information about the patterning process and also instructions for operation of image capture device 1240. The exemplary systems thus described improve OPC prediction accuracy and reduce OPC development cycle time.

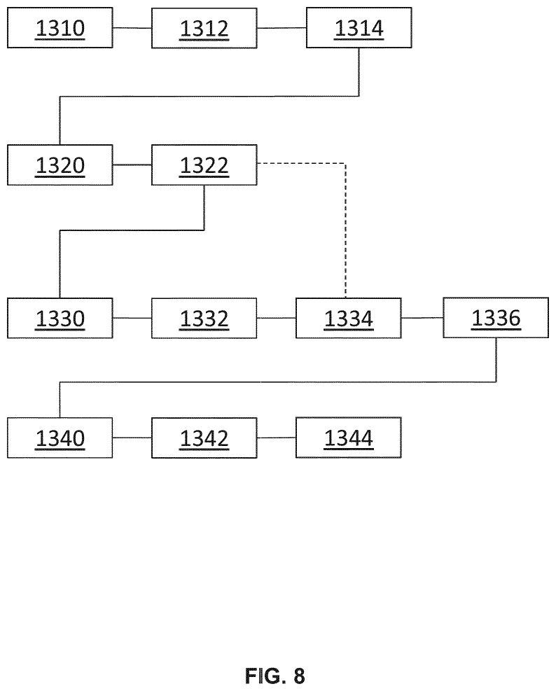

FIG. 8 is a process flow diagram of an example implementation of an improved metrology process, according to an embodiment.

A method for improving metrology according to the systems and embodiments described herein can include executing a process model on a computing cluster, such as cluster 1210. The process model can accept, at 1310, a reticle design. The process model can then generate, at 1312, a GDS layout specifying the target pattern. At 1314, the process model can then select one or more gauges extracted from good quality raw images selected according to the method 300.

An image capture device, for example image capture device 1240, can generate, at 1320, recipe 1230. Recipe 1230 can be used by image capture device 1240 to perform, at 1322, high-quality metrology on the printed pattern, including generating any number of high-resolution measured images. Further, based on the selection process of the method 300, a sub-set of good quality measured images can be transmitted to cluster 1210 for image processing.

Image processing can include, for example, executing image filtering at 1330, image alignment and averaging 1332, contour extraction 1334, and EP gauge extraction 1336. Image filtering can include, for example, automatic removal of misprinted images and/or low contrast images, based for example on permitted benchmarks or tolerances. Optionally, recipe 1230 and measured images 320 can be input from 1322, as part of the contour extraction process to increase metrology consistency by comparing measured images 320 before and after the image filtering and averaging alignment processes.

Model calibration and validation can be performed at 1340, where the EP gauges, CD gauges or other gauges extracted at 1336 can be received by one or more computing systems. The calibrated and validated model can be optimized, at 1340, to support a large number of EP gauges, for example an increase by a factor of 2, 3, 3.6, 5, 10, or more, over the number of CD gauges. At 1342, the process model can be calibrated and at 1344, the calibrated process model can be provided to a graphical user interface (GUI) for user review, refinement, transmission, or further processing.

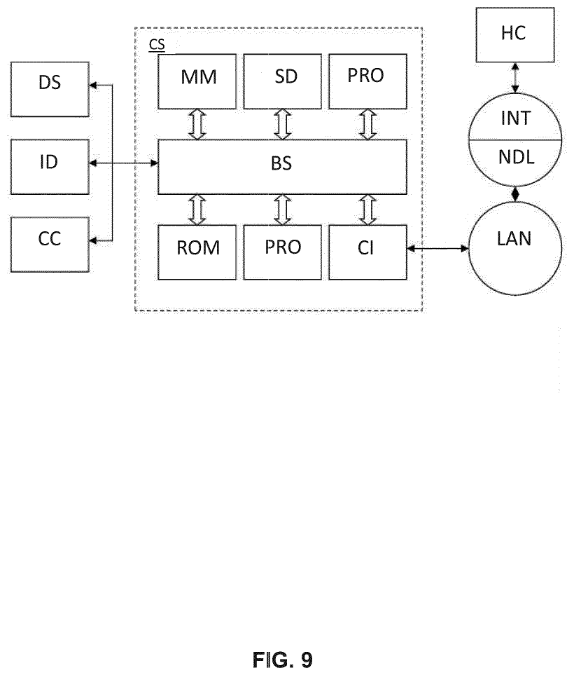

FIG. 9 is a block diagram of an example computer system CS, according to an embodiment.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

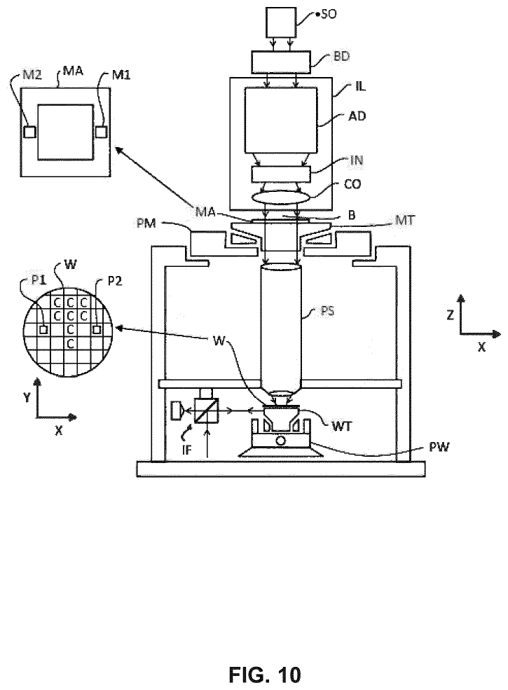

FIG. 10 is a schematic diagram of a lithographic projection apparatus, according to an embodiment.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning means (and interferometric measuring means IF), the substrate table WT can be moved accurately, e.g. so as to position different target portions C in the path of beam PB. Similarly, the first positioning means can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=1/4 or 1/5). In this manner, a relatively large target portion C can be exposed, without having to compromise on resolution.

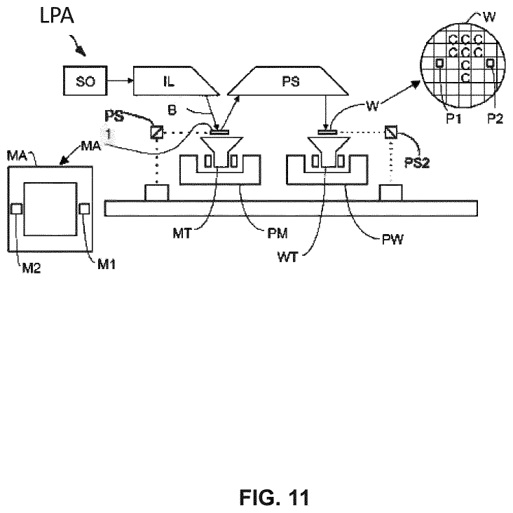

FIG. 11 is a schematic diagram of another lithographic projection apparatus (LPA), according to an embodiment.

LPA can include source collector module SO, illumination system (illuminator) IL configured to condition a radiation beam B (e.g. EUV radiation), support structure MT, substrate table WT, and projection system PS.

Support structure (e.g. a patterning device table) MT can be constructed to support a patterning device (e.g. a mask or a reticle) MA and connected to a first positioner PM configured to accurately position the patterning device;

Substrate table (e.g. a wafer table) WT can be constructed to hold a substrate (e.g. a resist coated wafer) W and connected to a second positioner PW configured to accurately position the substrate.

Projection system (e.g. a reflective projection system) PS can be configured to project a pattern imparted to the radiation beam B by patterning device MA onto a target portion C (e.g. comprising one or more dies) of the substrate W.

As here depicted, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser, not shown in FIG. 11, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g. patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de-)magnification and image reversal characteristics of the projection system PS.

In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

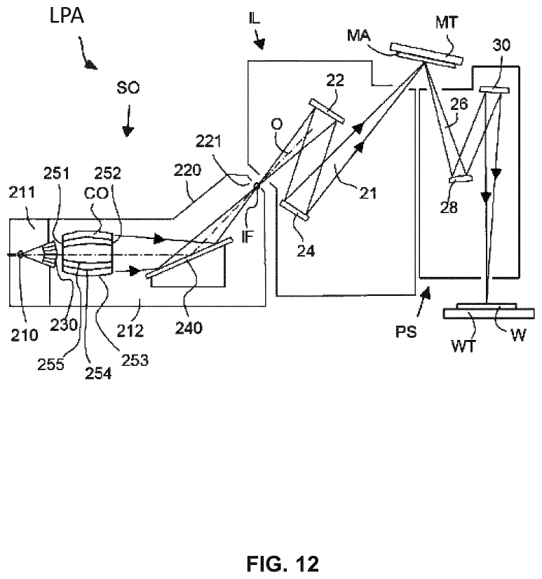

FIG. 12 is a detailed view of the lithographic projection apparatus, according to an embodiment.

As shown, LPA can include the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 12.

Collector optic CO, as illustrated in FIG. 12, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

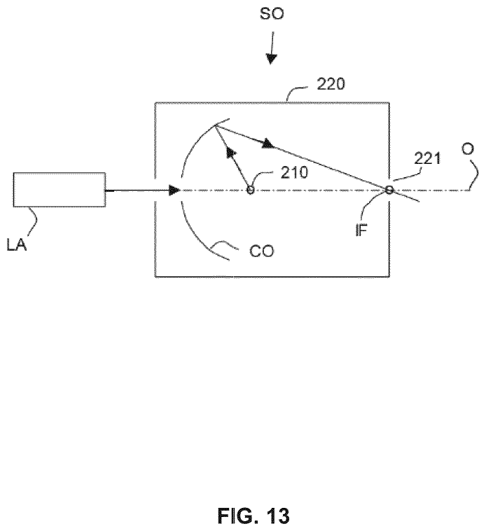

FIG. 13 is a detailed view of source collector module SO of lithographic projection apparatus LPA, according to an embodiment.

Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

FIG. 14 schematically depicts an embodiment of an electron beam inspection apparatus 1920, according to an embodiment. In an embodiment, the inspection apparatus may be an electron beam inspection apparatus (e.g., the same as or similar to a scanning electron microscope (SEM)) that yields an image of a structure (e.g., some or all the structure of a device, such as an integrated circuit) exposed or transferred on the substrate. A primary electron beam 1924 emitted from an electron source 1922 is converged by condenser lens 1926 and then passes through a beam deflector 1928, an E x B deflector 1930, and an objective lens 1932 to irradiate a substrate 1910 on a substrate table 1912 at a focus.

When the substrate 1910 is irradiated with electron beam 1924, secondary electrons are generated from the substrate 1910. The secondary electrons are deflected by the E x B deflector 1930 and detected by a secondary electron detector 1934. A two-dimensional electron beam image can be obtained by detecting the electrons generated from the sample in synchronization with, e.g., two dimensional scanning of the electron beam by beam deflector 1928 or with repetitive scanning of electron beam 1924 by beam deflector 1928 in an X or Y direction, together with continuous movement of the substrate 1910 by the substrate table 1912 in the other of the X or Y direction. Thus, in an embodiment, the electron beam inspection apparatus has a field of view for the electron beam defined by the angular range into which the electron beam can be provided by the electron beam inspection apparatus (e.g., the angular range through which the deflector 1928 can provide the electron beam 1924). Thus, the spatial extent of the field of the view is the spatial extent to which the angular range of the electron beam can impinge on a surface (wherein the surface can be stationary or can move with respect to the field).

A signal detected by secondary electron detector 1934 is converted to a digital signal by an analog/digital (A/D) converter 1936, and the digital signal is sent to an image processing system 1950. In an embodiment, the image processing system 1950 may have memory 1956 to store all or part of digital images for processing by a processing unit 1958. The processing unit 1958 (e.g., specially designed hardware or a combination of hardware and software or a computer readable medium comprising software) is configured to convert or process the digital images into datasets representative of the digital images. In an embodiment, the processing unit 1958 is configured or programmed to cause execution of a method described herein. Further, image processing system 1950 may have a storage medium 1956 or 1952 configured to store the digital images and corresponding datasets in a reference database. A display device 1954 may be connected with the image processing system 1950, so that an operator can conduct necessary operation of the equipment with the help of a graphical user interface.

FIG. 15 schematically illustrates a further embodiment of an inspection apparatus, according to an embodiment. The system is used to inspect a sample 90 (such as a substrate) on a sample stage 88 and comprises a charged particle beam generator 81, a condenser lens module 82, a probe forming objective lens module 83, a charged particle beam deflection module 84, a secondary charged particle detector module 85, and an image forming module 86.

The charged particle beam generator 81 generates a primary charged particle beam 91. The condenser lens module 82 condenses the generated primary charged particle beam 91. The probe forming objective lens module 83 focuses the condensed primary charged particle beam into a charged particle beam probe 92. The charged particle beam deflection module 84 scans the formed charged particle beam probe 92 across the surface of an area of interest on the sample 90 secured on the sample stage 88. In an embodiment, the charged particle beam generator 81, the condenser lens module 82 and the probe forming objective lens module 83, or their equivalent designs, alternatives or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly forming at least one scanned image. In an embodiment, the secondary charged particle detector module 85 and image forming module 86, or their equivalent designs, alternatives or any combination thereof, together form an image forming apparatus which forms a scanned image from detected secondary charged particles emitted from sample 90 being bombarded by the charged particle beam probe 92.

In an embodiment, a monitoring module 87 is coupled to the image forming module 86 of the image forming apparatus to monitor, control, etc. the patterning process and/or derive a parameter for patterning process design, control, monitoring, etc. using the scanned image of the sample 90 received from image forming module 86. So, in an embodiment, the monitoring module 87 is configured or programmed to cause execution of a method described herein. In an embodiment, the monitoring module 87 comprises a computing device. In an embodiment, the monitoring module 87 comprises a computer program to provide functionality herein and encoded on a computer readable medium forming, or disposed within, the monitoring module 87.

In an embodiment, like the electron beam inspection tool of FIG. 14 that uses a probe to inspect a substrate, the electron current in the system of FIG. 15 is significantly larger compared to, e.g., a CD SEM such as depicted in FIG. 14, such that the probe spot is large enough so that the inspection speed can be fast. However, the resolution may not be as high as compared to a CD SEM because of the large probe spot.

The SEM images, from, e.g., the system of FIG. 14 and/or FIG. 15, may be processed to extract contours that describe the edges of objects, representing device structures, in the image. These contours are then typically quantified via metrics, such as CD, at user-defined cut-lines. Thus, typically, the images of device structures are compared and quantified via metrics, such as an edge-to-edge distance (CD) measured on extracted contours or simple pixel differences between images. Alternatively, metrics can include EP gauges as described herein.

Now, besides measuring substrates in a patterning process, it is often desirable to use one or more tools to produce results that, for example, can be used to design, control, monitor, etc. the patterning process. To do this, there may be provided one or more tools used in computationally controlling, designing, etc. one or more aspects of the patterning process, such as the pattern design for a patterning device (including, for example, adding sub-resolution assist features or optical proximity corrections), the illumination for the patterning device, etc. Accordingly, in a system for computationally controlling, designing, Etc. a manufacturing process involving patterning, the major manufacturing system components and/or processes can be described by various functional modules. In particular, in an embodiment, one or more mathematical models can be provided that describe one or more steps and/or apparatuses of the patterning process, including typically the pattern transfer step. In an embodiment, a simulation of the patterning process can be performed using one or more mathematical models to simulate how the patterning process forms a patterned substrate using a measured or design pattern provided by a patterning device.

Embodiments of the present disclosure can be further described by the following clauses.

1. A non-transitory computer-readable medium comprising instructions stored therein that, when executed by one or more processors, cause operations comprising:

obtaining a plurality of raw images of a patterned substrate;

determining a raw image quality metric based on data associated with gauges or contours of one or more features within each image of the plurality of raw images, the raw image quality metric being indicative of a raw image quality;

selecting, based on the raw image quality metric, a sub-set of raw images from the plurality of raw images; and

providing the sub-set of raw images for performing measurements associated with the one or more features within an image.

2. The medium of clause 1, wherein the determining the raw image quality metric comprises:

analyzing, based on specified criteria, gauge data associated with the gauges each image of the plurality of raw images.

3. The medium of clause 2, wherein the analyzing comprises:

determining whether the gauge data associated with the gauges exists for a given raw image of the plurality of images;

responsive to the gauge data not existing, assigning a first value to the raw image quality metric, the first value being lower than a selection threshold; or

responsive to the gauge data exists, assigning a second value to the raw image quality metric, the second value being relatively higher than the selection threshold.

4. The medium of clause 3, wherein the determining the raw image quality metric further comprises:

determining whether the gauge data is missing CD gauges for the given raw image of the plurality of images; and

responsive the missing CD gauges, reducing the second value of the raw image quality metric by a specified amount.

5. The medium of clause 4, wherein the specified amount is computed as an inverse of a product of a number of gauge types and a number of repeating patterns.
6. The medium of clause 3, wherein the determining the raw image quality metric further comprises:

clustering the gauge data associated with the gauges of the plurality of raw images, the gauge data being EP gauge data; and

modifying, based on the clustering, the second value of the raw image quality metric.

7. The medium of clause 6, wherein the modifying the second value of the raw image quality metric comprises:

determining whether the EP gauge data of one or more raw images of the plurality of raw images are outside a specified cluster region; and

responsive to the EP gauge data being outside the specified cluster region, reducing the second value of the raw image quality metric associated with the one or more raw images to be lower than the selection threshold.

8. The medium of clause 6, wherein the modifying the second value of the raw image quality metric comprises:

determining whether the EP gauge data of one or more raw images of the plurality of raw images are within a specified cluster region; and

responsive to the EP gauge data being within the specified cluster region, modifying the second value of the raw image quality metric associated with the one or more raw images based on a statistic associated with CD gauge data.

9. The medium of clause 8, wherein the modifying the second value of the raw image quality metric comprises:

determining whether the statistic associated with the CD gauge data are outside a statistic threshold; and

responsive the CD gauge data being outside the statistic threshold, reducing the second value of the raw image quality metric of the one or more raw images by a specified amount.

10. The medium of clause 9, wherein the specified amount is computed as an inverse of a product of number of gauge types and number of repeating patterns.
11. The medium of any of clauses 2-10, further comprising:

generating an issue report for each raw image whose raw image quality metric that does not satisfy the selection threshold.

12. The medium of clause 1, wherein the determining the raw image quality metric comprises:

performing statistical analysis on gauge data of the gauges associated with each raw image to generate the raw image quality metric.

13. The medium of clause 12, wherein the raw image quality metric is a function of a contrast at the gauges associated with each raw image.
14. The medium of clause 13, wherein the raw image quality metric is an average of slopes determined at the gauges associated with each raw image.
15. The medium of clause 14, wherein a slope of a given gauge measures a steepness of a given image in transition from relatively bright region to dark region at a given gauge.
16. The medium of clause 1, wherein the determining of the raw image quality metric comprises:

obtaining a first contour of a feature within an average image of the plurality of raw images associated with a particular pattern;

obtaining a second contour of the feature from each of the raw image associated with the particular pattern; and

determining a distance between the first contour with the second contour.

17. The medium of clause 16, wherein the average image is obtained by:

clustering of the raw images based on a characteristic of the feature; and

averaging a cluster of raw images within a specified cluster region.

18. The medium of clause 17, wherein the average image is obtained by:

aligning the raw images of the particular pattern;

clustering the raw images based on mutual distances between contours of a feature within each of the raw images;

averaging the cluster of raw images within the specified cluster region to determine the average image; and

extracting the first contour from the average image.

19. The medium of clause 16, wherein the obtaining of the second contour comprises:

determining an image property at contour locations associated with the feature within a given raw image;

determining whether the image property breaches a threshold; and

responsive to the image property breaching the threshold, extracting the second contour of the feature from the given raw image.

20. The medium of clause 19, wherein the image property is an local edge sharpness or contrast value at a location associated with the feature, or intensity at a contour of the feature.
21. The medium of clause 1, wherein the determining of the raw image quality metric comprises:

obtaining contours of a feature within each raw image of the plurality of raw images associated with a particular pattern; and

determining matrix of a distance between a contour of each raw image of the plurality of raw images with a contour of each another raw image of the plurality of raw images.

22. The medium of clause 21, further comprising:

selecting, based on the distance matrix, the sub-set of raw images that satisfy a selection threshold.

23. The medium of any of clauses 1-22, wherein the plurality of raw images are SEM images acquired via a scanning electron microscope (SEM).
24. A method for selecting captured images of a patterned substrate, the method comprising:

obtaining a plurality of raw images of a patterned substrate;

determining a raw image quality metric based on data associated with gauges or contours of one or more features within each image of the plurality of raw images, the raw image quality metric being indicative of a raw image quality;

selecting, based on the raw image quality metric, a sub-set of raw images from the plurality of raw images; and

providing the sub-set of raw images for performing measurements associated with the one or more features within an image.

25. The method of clause 24, wherein the determining the raw image quality metric comprises:

analyzing, based on specified criteria, gauge data associated with the gauges each image of the plurality of raw images.

26. The method of clause 25, wherein the analyzing comprises:

determining whether the gauge data associated with the gauges exists for a given raw image of the plurality of images;

responsive to the gauge data not existing, assigning a first value to the raw image quality metric, the first value being lower than a selection threshold; or

responsive to the gauge data exists, assigning a second value to the raw image quality metric, the second value being relatively higher than the selection threshold.

27. The method of clause 26, wherein the determining the raw image quality metric further comprises:

determining whether the gauge data is missing CD gauges for the given raw image of the plurality of images; and

responsive the missing CD gauges, reducing the second value of the raw image quality metric by a specified amount.

28. The method of clause 27, wherein the specified amount is computed as an inverse of a product of a number of gauge types and a number of repeating patterns.
29. The method of clause 26, wherein the determining the raw image quality metric further comprises:

clustering the gauge data associated with the gauges of the plurality of raw images, the gauge data being EP gauge data; and

modifying, based on the clustering, the second value of the raw image quality metric.

30. The method of clause 29, wherein the modifying the second value of the raw image quality metric comprises:

determining whether the EP gauge data of one or more raw images of the plurality of raw images are outside a specified cluster region; and

responsive to the EP gauge data being outside the specified cluster region, reducing the second value of the raw image quality metric associated with the one or more raw images to be lower than the selection threshold.

31. The method of clause 29, wherein the modifying the second value of the raw image quality metric comprises:

determining whether the EP gauge data of one or more raw images of the plurality of raw images are within a specified cluster region; and

responsive to the EP gauge data being within the specified cluster region, modifying the second value of the raw image quality metric associated with the one or more raw images based on a statistic associated with CD gauge data.

32. The method of clause 31, wherein the modifying the second value of the raw image quality metric comprises:

determining whether the statistic associated with the CD gauge data are outside a statistic threshold; and

responsive the CD gauge data being outside the statistic threshold, reducing the second value of the raw image quality metric of the one or more raw images by a specified amount.

33. The method of clause 32, wherein the specified amount is computed as an inverse of a product of number of gauge types and number of repeating patterns.
34. The method of any of clauses 25-33, further comprising:

generating an issue report for each raw image whose raw image quality metric that does not satisfy the selection threshold.

35. The method of clause 24, wherein the determining the raw image quality metric comprises:

performing statistical analysis on gauge data of the gauges associated with each raw image to generate the raw image quality metric.

36. The method of clause 35, wherein the raw image quality metric is a function of a contrast at the gauges associated with each raw image.
37. The method of clause 36, wherein the raw image quality metric is an average of slopes determined at the gauges associated with each raw image.
38. The method of clause 37, wherein a slope of a given gauge measures a steepness of a given image in transition from relatively bright region to dark region at a given gauge.
39. The method of clause 24, wherein the determining of the raw image quality metric comprises:

obtaining a first contour of a feature within an average image of the plurality of raw images associated with a particular pattern or a reference raw image selected from the raw images;

obtaining a second contour of the feature from each of the raw image associated with the particular pattern; and

determining a distance between the first contour with the second contour.

40. The method of clause 39, wherein the average image is obtained by:

clustering of the raw images based on a characteristic of the feature; and

averaging a cluster of raw images within a specified cluster region.

41. The method of clause 40, wherein the average image is obtained by:

aligning the raw images of the particular pattern;

clustering the raw images based on mutual distances between contours of a feature within each of the raw images;

averaging the cluster of raw images within the specified cluster region to determine the average image; and

extracting the first contour from the average image.

42. The method of clause 39, wherein the obtaining of the second contour comprises:

determining an image property at contour locations associated with the feature within a given raw image;

determining whether the image property breaches a threshold; and

responsive to the image property breaching the threshold, extracting the second contour of the feature from the given raw image.

43. The method of clause 42, wherein the image property is a local edge sharpness or contrast value at a location associated with the feature, or intensity at a contour of the feature.
44. The method of clause 24, wherein the determining of the raw image quality metric comprises:

obtaining contours of a feature within each raw image of the plurality of raw images associated with a particular pattern; and

determining matrix of a distance between a contour of each raw image of the plurality of raw images with a contour of each another raw image of the plurality of raw images.

45. The method of clause 44, further comprising:

selecting, based on the distance matrix, the sub-set of raw images that satisfy a selection threshold.

46. The method of any of clauses 1-45, wherein the plurality of raw images are SEM images acquired via a scanning electron microscope (SEM).

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The descriptions herein are intended to be illustrative, not limiting. Thus, it will be apparent to one skilled in the art that modifications may be made as described without departing from the scope of the claims set out below.

1. A non-transitory computer-readable medium comprising instructions stored therein that, when executed by one or more processors, are configured to the one or more processors to at least:
obtain a plurality of raw images of a patterned substrate;
determine a raw image quality metric based on data associated with one or more gauges or one or more contours of one or more features within each image of the plurality of raw images, the raw image quality metric being indicative of a raw image quality;
select, based on the raw image quality metric, a sub-set of raw images from the plurality of raw images; and
provide the sub-set of raw images for performing measurements associated with the one or more features within an image.

2. The medium of claim 1, wherein the instructions configured to determine the raw image quality metric are further configured to cause the one or more processors to analyze, based on specified criteria, gauge data associated with the gauges of each image of the plurality of raw images.

3. The medium of claim 2, wherein the instructions configured to analyze gauge data are further configured to cause the one or more processors to:
determine whether the gauge data associated with the gauges exists for a given raw image of the plurality of images;
responsive to the gauge data not existing, assign a first value to the raw image quality metric; and
responsive to the gauge data existing, assign a second value to the raw image quality metric different than the first value.

4. The medium of claim 3, wherein the instructions configured to determine the raw image quality metric are further configured to cause the one or more processors to:
determine whether the gauge data is missing one or more CD gauges for the given raw image of the plurality of images; and
responsive to one or more CD gauges being missing, reduce the second value of the raw image quality metric by a specified amount.

5. The medium of claim 4, wherein the specified amount is related to a number of gauge types and a number of repeating patterns.

6. The medium of claim 3, wherein the instructions configured to determine the raw image quality metric are further configured to cause the one or more processors to:
cluster the gauge data associated with the gauges of the plurality of raw images, the gauge data being edge placement (EP) gauge data; and
modify, based on the clustering, the second value of the raw image quality metric.

7. The medium of claim 6, wherein the instructions configured to modify the second value of the raw image quality metric are further configured to cause the one or more processors to:
determine whether the EP gauge data of one or more raw images of the plurality of raw images are within a specified cluster region; and
responsive to the EP gauge data being within the specified cluster region, modify the second value of the raw image quality metric associated with the one or more raw images.

8. The medium of claim 7, wherein the modification of the second value of the raw image quality metric is based on a statistic associated with CD gauge data, and wherein the instructions configured to modify the second value of the raw image quality metric are further configured to cause the one or more processors to:
determine whether the statistic associated with the CD gauge data is outside a statistic threshold; and
responsive the statistic associated with the CD gauge data being outside the statistic threshold, reduce the second value of the raw image quality metric of the one or more raw images by a specified amount.

9. The medium of claim 1, wherein the instructions configured to determine the raw image quality metric are further configured to cause the one or more processors to perform statistical analysis on gauge data of the gauges associated with each raw image to generate the raw image quality metric.

10. The medium of claim 9, wherein the raw image quality metric indicates a contrast at the gauges associated with each raw image.

11. The medium of claim 10, wherein the raw image quality metric indicates an average of slopes determined at the gauges associated with each raw image.

12. The medium of claim 1, wherein the instructions configured to determine the raw image quality metric are further configured to cause the one or more processors to:
obtain a first contour of a feature within an average image of the plurality of raw images associated with a particular pattern;
obtain a second contour of the feature from each of the raw images associated with the particular pattern; and
determine a distance between the first contour with the second contour.

13. The medium of claim 12, wherein the average image is obtained by:
clustering of the raw images based on a characteristic of the feature; and
averaging a cluster of raw images within a specified cluster region.

14. The medium of claim 12, wherein the instructions configured to obtain the second contour are further configured to cause the one or more processors to:
determine an image property at contour locations associated with the feature within a given raw image;
determine whether the image property breaches a threshold; and
responsive to the image property breaching the threshold, extract the second contour of the feature from the given raw image.

15. The medium of claim 14, wherein the image property is a local edge sharpness or contrast value at a location associated with the feature, or intensity at a contour of the feature.

16. The medium of claim 1, wherein the instructions configured to determine the raw image quality metric are further configured to cause the one or more processors to:
obtain contours of a feature within each raw image of the plurality of raw images associated with a particular pattern; and
determine a matrix of a distance between a contour of each raw image of the plurality of raw images with a contour of each another raw image of the plurality of raw images.

17. A method comprising:
obtaining a plurality of raw images of a patterned substrate;
determining a raw image quality metric based on data associated with one or more gauges or one or more contours of one or more features within each image of the plurality of raw images, the raw image quality metric being indicative of a raw image quality;
selecting, by a hardware computer and based on the raw image quality metric, a sub-set of raw images from the plurality of raw images; and
providing the sub-set of raw images for performing measurements associated with the one or more features within an image.

18. The method of claim 17, wherein the determining the raw image quality metric comprises analyzing, based on specified criteria, gauge data associated with gauges of each image of the plurality of raw images.

19. The method of claim 18, wherein the analyzing comprises:
determining whether the gauge data associated with the gauges exists for a given raw image of the plurality of images; and
responsive to the gauge data not existing, assigning a first value to the raw image quality metric, the first value being lower than a selection threshold, or responsive to the gauge data existing, assigning a second value to the raw image quality metric, the second value being relatively higher than the selection threshold.

20. The method of claim 19, wherein the determining the raw image quality metric further comprises:
determining whether the gauge data is missing one or more CD gauges for the given raw image of the plurality of images; and
responsive to one or more CD gauges being missing, reducing the second value of the raw image quality metric by a specified amount.
